(19) United States
(12) Patent Application Publication
(10) Pub. No.: US 2024/0065083 A1
(43) Pub. Date: Feb. 22, 2024

(54) Display Device

(71) Applicant: Sony Group Corporation, Tokyo (JP)

(72) Inventors: Yoshinori Ikuma, Tokyo (JP); Song Han, Tokyo (JP); Yohei Shimizu, Chiba (JP); Yoshimi Saito, Kanagawa (JP); Yuji Arai, Kanagawa (JP); Tomio Aoki, Kanagawa (JP); Yasutake Furukoshi, Kanagawa (JP)

(73) Assignee: Sony Group Corporation, Tokyo (JP)

(21) Appl. No.: 18/270,042

(22) PCT Filed: Dec. 21, 2021
(86) PCT No.: PCT/JP2021/047255

§ 371 Date: Jun. 28, 2023

(30) Foreign Application Priority Data
Jan. 4, 2021 (JP) 2021-000070

(51) Int. Cl. H10K 59/80

(52) U.S. Cl. CPC H10K 59/8794

(57) ABSTRACT

The present disclosure relates a display device that can enhance thermal diffusion performance of a display panel in its plane direction.

The display device includes a plate-shaped display cell that displays an image, and a thin plate-shaped heat conduction member stuck on a rear face side of the display cell. The heat conduction member is formed with a thickness of approximately 0.3 to 1.0 mm. The technology according to the present disclosure can be applied, for example, to a television receiver or a display in which an OLED cell is used.

### TECHNICAL FIELD

The present disclosure relates a display device, and particularly to a display device that can enhance thermal diffusion performance of a display panel in its plane direction.

### BACKGROUND ART

Display devices using organic EL (Electro Luminescence) elements are superior to display devices using liquid crystals in that a backlight is unnecessary because the organic EL elements themselves emit light and that the response speed to an electric current is high. Meanwhile, organic EL elements have a problem that heat stays inside the organic EL elements due to heat generation during driving.

In this regard, it is disclosed in PTL 1 that a heat radiation member is provided in a stacking direction of organic EL elements so as to prevent the configuration of the organic EL elements from becoming complicated.

### CITATION LIST

### Patent Literature

[PTL 1]
Japanese Patent Laid-Open No. 2017-195135

### SUMMARY

### Technical Problem

However, the configuration in PTL 1 focuses on heat radiation performance of individual organic EL elements, and although it can improve heat radiation of the display panel in its thicknesswise direction, it does not improve heat radiation of the display panel in its plane direction.

The present disclosure has been made in view of such a situation and makes it possible to enhance thermal diffusion performance of a display panel in its plane direction.

### Solution to Problem

The display device according to the present disclosure is a display device including a plate-shaped display cell that displays an image, and a thin plate-shaped heat conduction member stuck on a rear face side of the display cell, and the heat conduction member is formed with a thickness of approximately 0.3 to 1.0 mm.

In the present disclosure, in the display device including the plate-shaped display cell that displays an image and the thin plate-shaped heat conduction member stuck on the rear face side of the display cell, the heat conduction member is formed with a thickness of approximately 0.3 to 1.0 mm.

### BRIEF DESCRIPTION OF DRAWINGS

FIG. 1 is a view depicting an example of a side face configuration of a display device.

FIG. 2 is a view depicting an example of a back face configuration of the display device.

FIG. 3 is a view depicting an example of the back face configuration of the display device with a back chassis removed.

FIG. 4 is a view depicting an example of a cross sectional configuration of the display device.

FIG. 5 is a view depicting an example of a configuration of a display device to which the technology according to the present disclosure is applied.

FIG. 6 is a view depicting the example of the configuration of the display device to which the technology according to the present disclosure is applied.

FIG. 7 is a view illustrating a method for evaluating thermal diffusion performance of heat conduction members.

FIG. 8 is a view depicting evaluation results of the thermal diffusion performance.

FIG. 9 is a view illustrating a method for evaluating an element lifetime attributable to heat conduction members.

FIG. 10 is a view illustrating blinking patterns of a display cell.

FIG. 11 is a view illustrating an thermal diffusion effect by heat conduction members.

FIG. 12 is a view illustrating an element degradation suppression effect by heat conduction members.

FIG. 13 is a view illustrating a method for evaluating a sound influence of a heat conduction member.

FIG. 14 is a view depicting an evaluation result of the sound influence.

### DESCRIPTION OF EMBODIMENT

In the following, a mode for carrying out the present disclosure (hereinafter referred to as an embodiment) is described. It is to be noted that the description is given in the following order:
1. Outline of Conventional Technology and Technology According to Present Disclosure
2. Configuration of Display Device
3. Evaluation of Thermal Diffusion Performance
4. Evaluation of Element Lifetime
5. Evaluation of Sound Influence

### 1. Outline of Conventional Technology and Technology According to Present Disclosure

### (Conventional Technology)

In a display device using OLED (Organic Light Emitting Diode) elements (also called organic EL elements), when luminance is increased, a surface temperature of an OLED cell increases due to heat generation of a control board disposed on a back face of the OLED cell and heat generation of the OLED cell itself. Since such heat generation has an influences on a degradation rate (lifetime) of the OLED elements, it is necessary to prevent the highest temperature in a temperature distribution of a surface of the OLED cell from exceeding specifications of the OLED cell.

PTL 1 discloses that a heat radiation member is provided in a stacking direction of organic EL elements so as to prevent the configuration of the organic EL elements from becoming complicated. However, this configuration focuses on heat radiation performance of individual organic EL elements, and, even though the configuration can improve the heat radiation of the OLED cell (display panel) in its thicknesswise direction, it does not improve the heat radiation of the OLED cell in its plane direction.

Further, there is known a configuration in which an OLED cell is vibrated by an actuator to output sound from a display surface. In a display device having such a configuration, since a space for vibration (amplitude) is necessary between the OLED cell and a back cover on a rear face side of the OLED cell, it is difficult to effectively radiate heat of the OLED cell to the back cover.

From the foregoing, enhancement of luminance of a display device is dependent upon improvement of light emission efficiency of an OLED cell itself, and this cannot easily be implemented by finished product manufactures that manufacture television receivers or displays using the OLED cell.

To cope with this situation, there is a case in which an aluminum (Al) plate of, for example, 3.0 mm thick (hereinafter referred to as t3.0 or the like) is stuck on a rear face of an OLED cell. With this configuration, it is possible to dissipate the heat of the OLED cell with use of the heat capacity of the Al plate to thereby enhance the luminance of the entire screen.

However, using an Al plate of t3.0 requires a very high cost and leads to an increased weight. Further, in a case where an Al plate of such a thickness is applied to a configuration in which an OLED cell is vibrated by an actuator, vibration of the OLED cell is suppressed, resulting in a decrease in sound pressure.

### Outline of Technology According to Present Disclosure

In the technology according to the present disclosure, a thin plate-shaped (sheet-shaped) heat conduction member is stuck on an Encapsulating substrate (encapsulation material) on the rear face of an OLED cell to enhance thermal diffusion performance of the OLED cell in its plane direction.

This makes it possible to lower a peak temperature of the surface of the OLED cell by heat conduction in the plane direction from a location at which the temperature is high to another location at which the temperature is low in a temperature distribution of the surface of the OLED cell, to thereby achieve temperature equalization. Especially, in a technique for enhancing the luminance in a case where the luminance is to be raised partially and in a short period of time (hereinafter referred to as an instantaneous thrust) in the OLED cell, it is possible to achieve optimization of the thickness of the heat conduction member and the requested thermal diffusion performance.

Further, in a configuration in which an OLED cell is vibrated by an actuator, applying a thin plate-shaped heat conduction member enables establishment of a good balance between an output of the actuator and vibration of the OLED cell, and both the thermal diffusion performance and maintenance of the sound pressure that have a tradeoff relation to each other can be achieved.

### 2. Configuration of Display Device

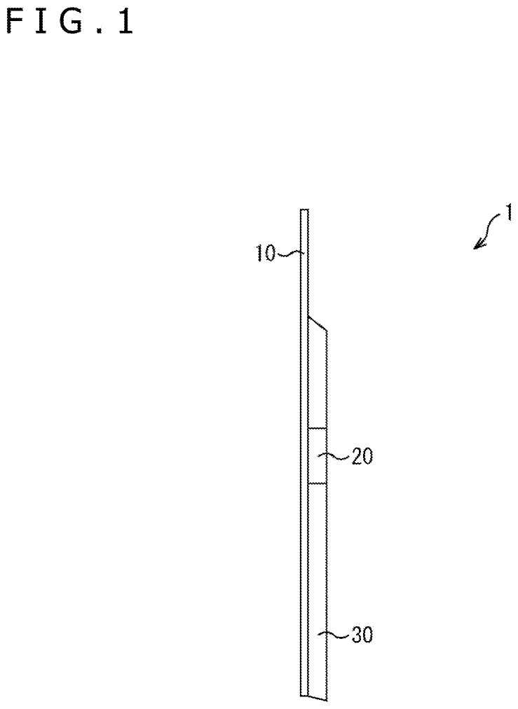

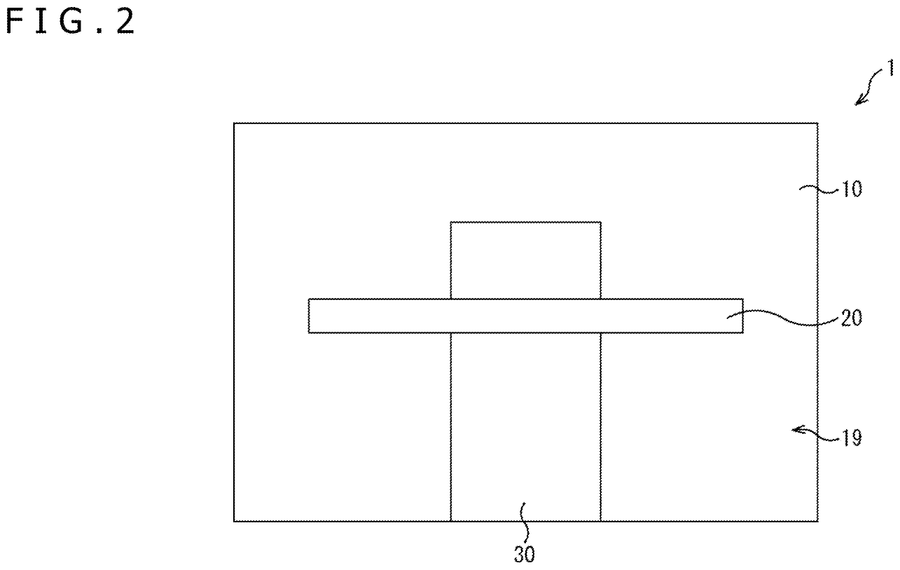

A configuration of a display device to which the technology according to the present disclosure can be applied is described. FIG. 1 is a view depicting an example of a side face configuration of the display device, and FIG. 2 is a view depicting an example of a back face configuration of the display device.

The display device 1 is a display device that displays an image, and is configured, for example, as a television receiver or a display in which an OLED cell is used. The display device 1 is configured such that sound can be outputted from a display surface thereof on which an image is displayed.

The display device 1 includes, for example, a panel unit 10 as a vibration plate, a vibration generation unit 20 that is disposed on a rear face of the panel unit 10 and vibrates the panel unit 10, and a signal processing unit 30 that controls the vibration generation unit 20.

The vibration generation unit 20 and the signal processing unit 30 are disposed on the rear face of the panel unit 10. The panel unit 10 has, on the rear face side thereof, a back chassis 19 that protects the panel unit 10, the vibration generation unit 20, and the signal processing unit 30. The back chassis 19 includes, for example, a plate-shaped metal plate or resin plate.

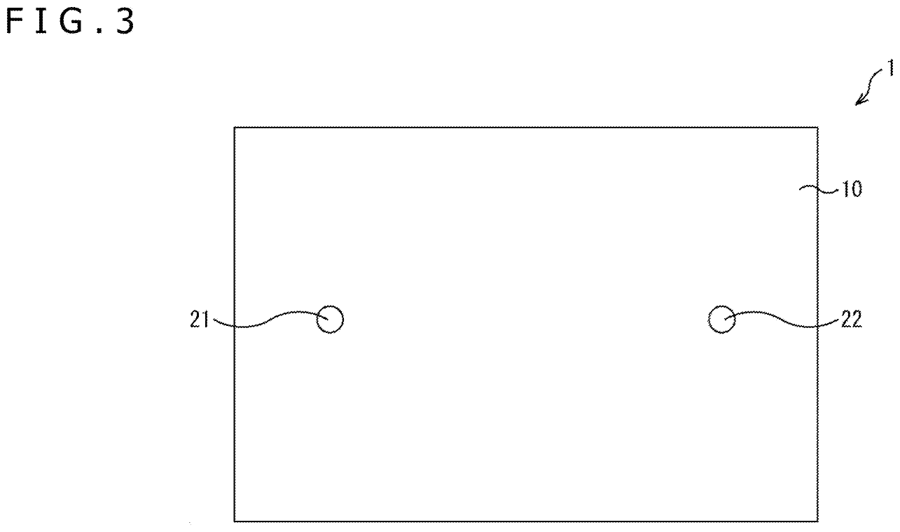

FIG. 3 is a view depicting an example of the back face configuration of the display device 1 (panel unit 10) with the back chassis 19 removed.

As hereinafter described, the panel unit 10 has a plate-shaped display cell that displays an image thereon, and an inner plate disposed in such a manner as to face the display cell with an air gap defined therebetween. As depicted in FIG. 3, two vibration generators 21 and 22 that configure the vibration generation unit 20 are disposed on the rear face side of the panel unit 10 (display cell).

The vibration generators 21 and 22 are disposed avoiding a location at which vibration is most likely to occur over overall audio frequencies (for example, 20 Hz to 20 kHz) when the display cell is vibrated by the vibration generators 21 and 22. The “location at which vibration is most likely to occur” is, for example, a position of an antinode of the greatest standing wave generated on the display cell when vibration is generated on the display cell by the vibration generators 21 and 22. Further, the vibration generators 21 and 22 are disposed avoiding a location at which vibration is least likely to occur over the overall audio frequencies when vibration is generated on the display cell by the vibration generators 21 and 22.

The vibration generator 21 and the vibration generator 22 have the same configuration. For example, each of the vibration generators 21 and 22 is configured as a speaker actuator as a vibration source that includes a voice coil, a bobbin around which the voice coil is wound, and a magnetic circuit. If a voice current of an electric signal flows to the voice coil in the vibration generator 21 or 22, a driving force is generated in the voice coil by the principle of an electromagnetic action. This driving force is transmitted to the display cell and causes the display cell to generate vibration according to a change in voice current, and accordingly, the air is vibrated to change the sound pressure.

By such a configuration, the display device 1 can output sound from the display surface thereof that displays an image.

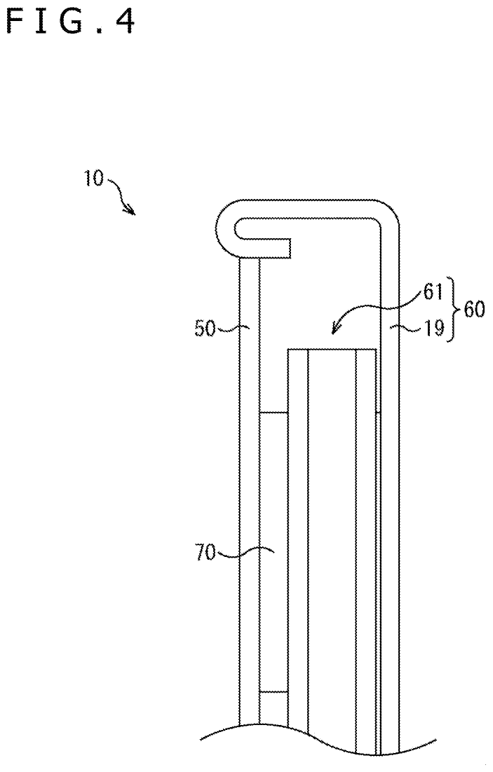

FIG. 4 is a view depicting an example of a cross sectional configuration of the display device 1 (panel unit 10).

The panel unit 10 of FIG. 4 configures a conventional display device to which the technology according to the present disclosure is not applied.

The panel unit 10 includes a display cell 50 and a back cover 60.

The display cell 50 is configured as a plate-shaped OLED cell that displays an image. The back cover 60 is disposed in such a manner as to protect a rear face side of the display cell 50 and includes a back chassis 19 and an inner plate 61 adhered to each other.

The inner plate 61 is disposed in such a manner as to face the display cell 50 with an air gap defined therebetween. Further, the inner plate 61 functions also as a member that supports the vibration generators 21 and 22 described hereinabove. The inner plate 61 has an opening, for example, at locations at which the vibration generators 21 and 22 (FIG. 3) are disposed.

A fixation member 70 is disposed between the display cell 50 and the inner plate 61. The fixation member 70 has a function of fixing the display cell 50 and the inner plate 61 to each other and a function as a spacer for keeping the air gap defined. The fixation member 70 includes, for example, a buffer layer of sponge or the like having an adhesive layer on opposite surfaces thereof.

In the configuration of FIG. 4, the rear face of the display cell 50 (face on the inner plate 61 side) includes an encapsulation material that seals the inside of the display cell 50. However, since thermal diffusion performance of the encapsulation material is not high at all, a temperature distribution of the surface of the display cell 50 suffers from unevenness.

Further, in the configuration of FIG. 4, in order for the display cell 50 to be vibrated by the vibration generators 21 and 22 to output sound, an air gap is defined between the display cell 50 and the inner plate 61. This air gap becomes a heat insulating layer and disturbs efficient dissipation of heat of the display cell 50 to the back cover 60.

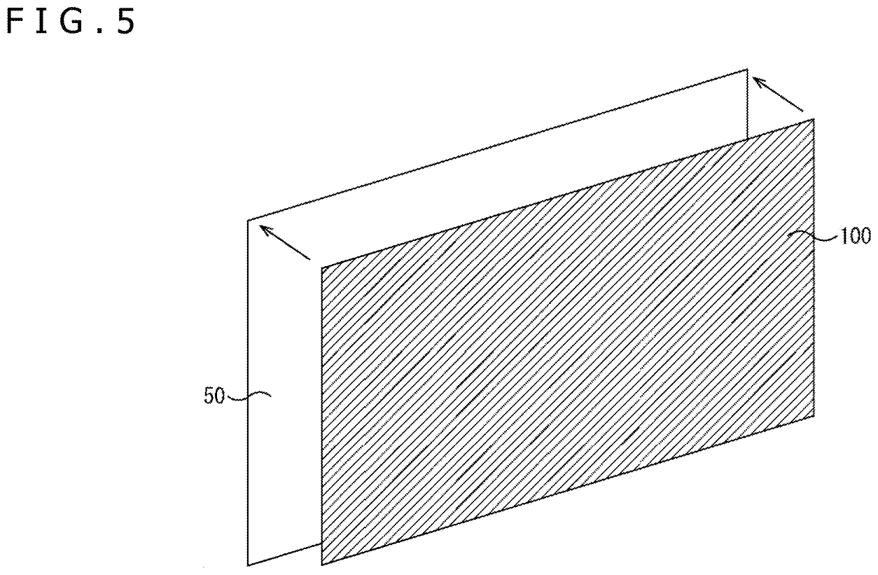

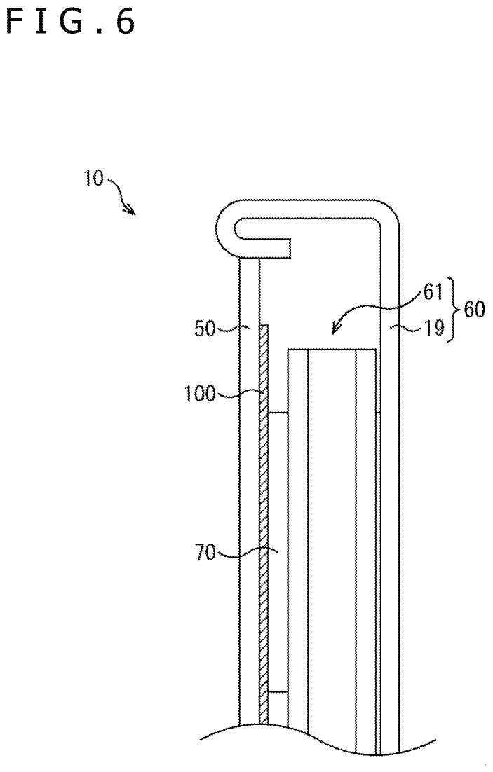

FIGS. 5 and 6 are views depicting an example of a configuration of a display device 1 (panel unit 10) to which the technology according to the present disclosure is applied. FIG. 5 depicts an example of a configuration of the rear face side of the display cell 50, and FIG. 6 depicts an example of a cross sectional configuration of the panel unit 10.

In the display device 1 to which the technology according to the present disclosure is applied, a thin plate-shaped heat conduction member 100 is stuck on the rear face (more particularly, the encapsulation material that configures the rear face) of the plate-shaped display cell 50 on which an image is displayed.

The heat conduction member 100 includes a material having a comparatively high heat conductivity such as aluminum, graphite, or copper. The heat conduction member 100 is formed with a thickness of approximately 0.3 to 1.0 mm. More preferably, the heat conduction member 100 is formed with a thickness of approximately 0.3 to 0.5 mm.

The heat conduction member 100 and the rear face of the display cell 50 are adhered to each other by a predetermined adhesive member. The adhesive member is, for example, a double-sided adhesive tape having a thickness of approximately 0.01 to 0.1 mm, an adhesive layer including a predetermined material, or the like.

The heat conduction member 100 is stuck on the rear face of the display cell 50, for example, in such a manner as to cover substantially the entire rear face of the display cell 50 as depicted in FIG. 5. In this case, the fixation member 70 fixes the heat conduction member 100 and the inner plate 61 to each other while keeping an air gap defined between the heat conduction member 100 and the inner plate 61 as depicted in FIG. 6.

With the configuration described above, it is possible to enhance the thermal diffusion performance of the display cell 50 in the plane direction.

Consequently, it becomes possible to lower a peak temperature of the surface of the display cell 50 by heat conduction in the plane direction from a location at which the temperature is high to another location at which the temperature is low in the temperature distribution of the surface of the display cell 50, to thereby achieve heat equalization. Especially, in the technique for enhancing the luminance at an instantaneous thrust in the display cell 50, it is possible to achieve optimization of the thickness of the heat conduction member 100 and the requested thermal diffusion performance.

Further, by setting the thickness of the heat conduction member 100 to approximately 0.3 to 1.0 mm, more preferably to approximately 0.3 to 0.5 mm, it is possible to maintain the sound pressure without suppressing vibration of the display cell 50 in the configuration in which the display cell 50 is vibrated to output sound.

The applicant performed evaluation of the thermal diffusion performance of the heat conduction member 100 and evaluation of the element lifetime attributable to the heat conduction member 100, in regard to the display device 1 (display cell 50) to which the technology according to the present disclosure is applied. In the following, evaluation methods and results thereof are described.

### 3. Evaluation of Thermal Diffusion Performance

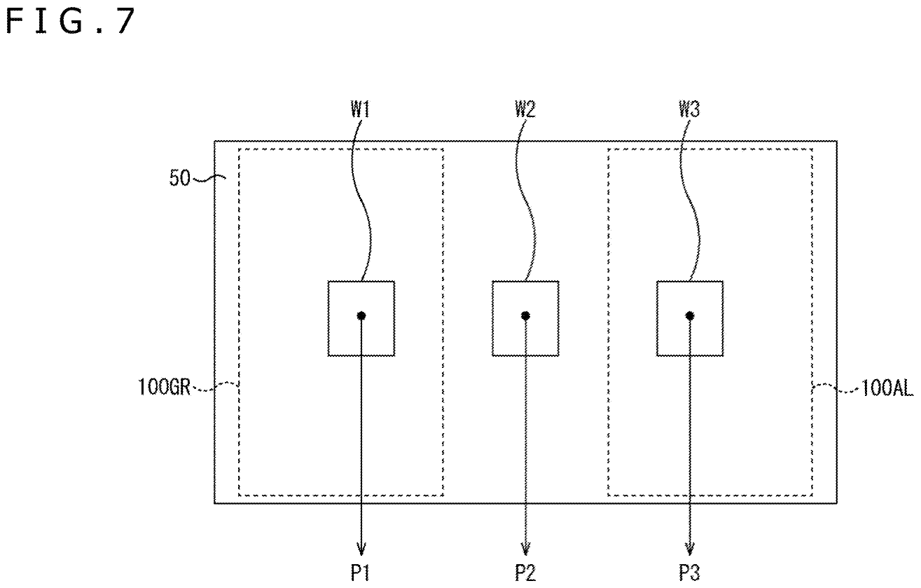

FIG. 7 is a view illustrating the method for evaluating the thermal diffusion performance of the heat conduction member 100 in regard to the display cell 50.

FIG. 7 depicts a configuration of a front face (display surface) side of the display cell 50. On the rear face of the display cell 50, on a left side region as viewed from the front face of the display cell 50, a heat conduction member 100GR including graphite is stuck, and on a right side region as viewed from the front face of the display cell 50, a heat conduction member 100AL including aluminum (Al) is stuck. Further, on the rear face of the display cell 50, between the heat conduction member 100GR and the heat conduction member 100AL, a region on which nothing is stuck (without any countermeasure) exists.

Here, it is assumed that the thickness of the heat conduction member 100GR is 0.3 mm and the thickness of the heat conduction member 100AL is 0.5 mm.

In such a state, evaluation of the thermal diffusion performance of the heat conduction members 100GR and 100AL is performed for the display cell 50. In particular, the temperature at positions P1, P2, and P3 in a case where rectangular regions (windows) W1, W2, and W3 on the display cell 50 are caused to emit light with a predetermined color (for example, magenta) for a fixed period of time and in another case in which the entire display cell 50 is caused to emit light for a fixed period of time.

The window W1 corresponds to the region in which the heat conduction member 100GR is stuck on the rear face of the display cell 50, and includes the position P1. The window W2 corresponds to the region in which nothing is stuck (without any countermeasure) on the rear face of the display cell 50, and includes the position P2. The window W3 corresponds to the region in which the heat conduction member 100AL is stuck on the rear face of the display cell 50, and includes the position P3. It is to be noted that emission of light from each of the windows W1, W2, and W3 assumes a partial instantaneous thrust, and emission of light from the entire screen reproduces a thermal equilibrium state obtained in a case where the luminance of the entire screen is increased.

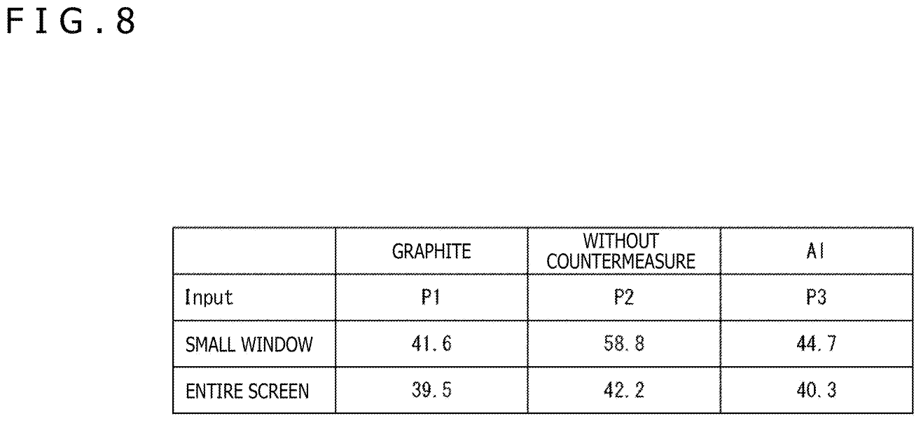

FIG. 8 depicts evaluation results of the thermal diffusion performance of the heat conduction members 100GR and 100AL.

In the case where the windows W1, W2, and W3 were caused to emit light, the temperature at the position P2 without any countermeasure was 58.8 degrees. Meanwhile, the temperature at the position P1 to which the heat conduction member 100GR (graphite) had been applied as the countermeasure was 41.6 degrees, and the temperature at the position P3 to which the heat conduction member 100AL (Al) had been applied as the countermeasure was 44.7 degrees.

In the case where the entire screen was caused to emit light, the temperature at the position P2 without any countermeasure was 42.2 degrees. Meanwhile, the temperature at the position P1 to which the heat conduction member 100GR (graphite) had been applied as the countermeasure was 39.5 degrees, and the temperature at the position P3 to which the heat conduction member 100AL (Al) had been applied as the countermeasure was 40.3 degrees.

That is, in the emission of light from the windows for which a partial instantaneous thrust was assumed, a heat suppression effect of 17.2 degrees was found in the case where the graphite (t0.3) was applied as the countermeasure, and a heat suppression effect of 14.1 degrees was found in the case where the aluminum (t0.5) was applied as the countermeasure, in comparison with the case without any countermeasure.

Further, in the emission of light from the entire screen which emission reproduced the thermal equilibrium state obtained in the case where the luminance of the entire screen was increased, a heat suppression effect of 2.7 degrees was found in the case where the graphite (t0.3) was applied as the countermeasure, and a heat suppression effect of 1.9 degrees was found in the case where the aluminum (t0.5) was applied as the countermeasure, in comparison with the case without any countermeasure.

In such a manner, while a high heat suppression effect is obtained by the heat conduction members 100GR and 100AL in regard to emission of light from the windows, the heat suppression effect obtained by the heat conduction members 100GR and 100AL is not high in regard to emission of light from the entire screen.

From the foregoing, it was confirmed that, in regard to emission of light for which an instantaneous thrust was assumed, the thermal diffusion performance of the heat conduction members 100GR and 100AL was high. It is to be noted that, in a case where the state in which the luminance of the entire screen is increased is continued for a fixed period of time, the heat capacity (thickness of the heat conduction member 100) becomes dominant in terms of the heat suppression effect. Accordingly, it is considered that the countermeasure that the thin plate-shaped heat conduction member 100 is stuck on the rear face of the display cell 50 is a technique suitable for an instantaneous thrust from a point of view of diffusion of heat that is increased partially in a short period of time.

It is to be noted that, where the heat conduction member 100GR and the heat conduction member 100AL are compared with each other in terms of the thermal diffusion performance, the thermal diffusion performance of the heat conduction member 100GR having a smaller thickness is higher. However, in a case where graphite and Al are compared with each other in molding of a thin plate-shaped heat conduction member, Al is superior from points of view of processability and cost, and therefore, it is preferable to apply Al as the material for the heat conduction member 100.

### 4. Evaluation of Element Lifetime

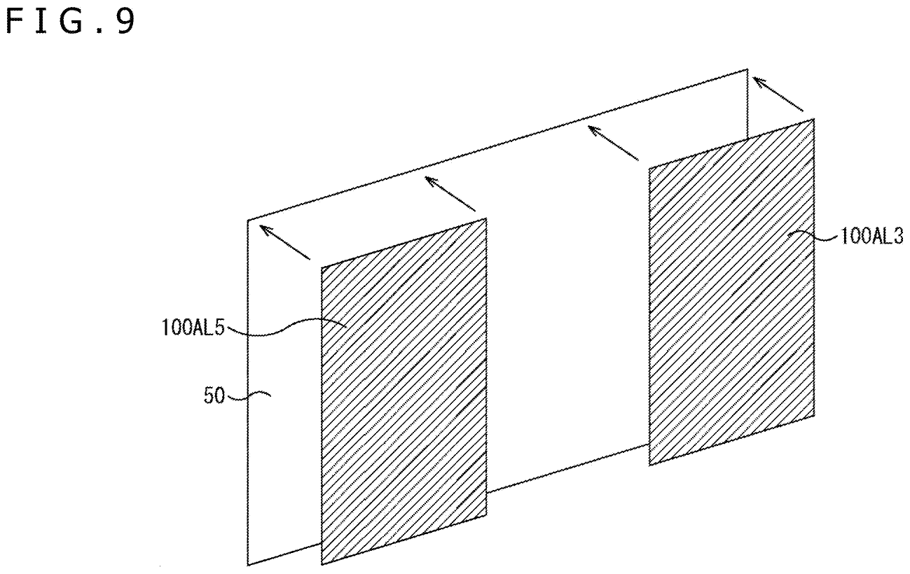

FIG. 9 is a view illustrating the method for evaluating the element lifetime attributable to heat conduction members 100 in regard to the display cell 50.

FIG. 9 depicts a configuration of the rear face side of the display cell 50. On the rear face of the display cell 50, on a region on the right side (region on the left side as viewed from the front face of the display cell 50), a heat conduction member 100AL3 of t0.3 including Al is stuck. On the rear face of the display cell 50, on a region on the left side (region on the right side as viewed from the front face of the display cell 50), a heat conduction member 100AL5 of t0.5 including Al is stuck. Further, on the rear face of the display cell 50, between the heat conduction member 100AL3 and the heat conduction member 100AL5, a region on which nothing is stuck (without Al) exists.

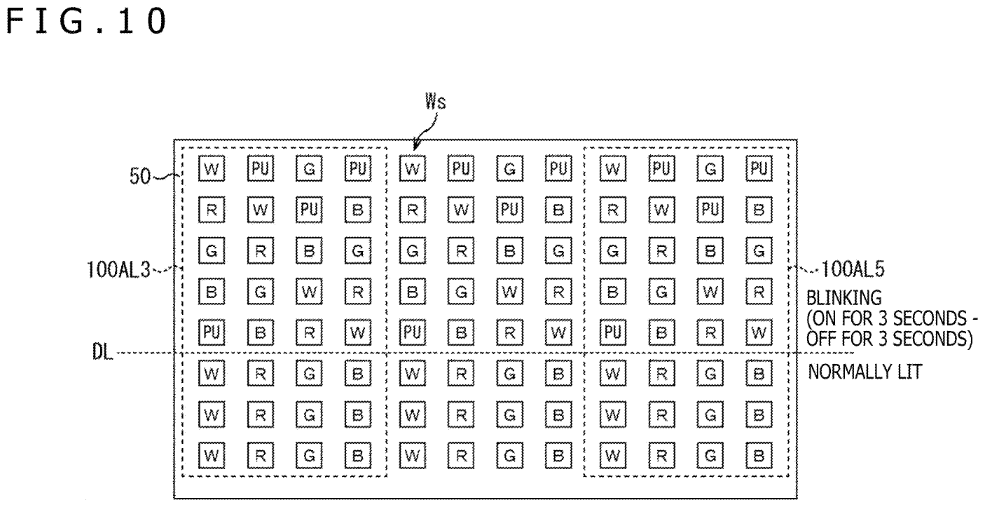

In such a state, the lifetime (degradation suppression effect) of the elements (OLED elements) attributable to the heat conduction members 100GR and 100AL is evaluated in regard to the display cell 50. Here, as depicted in FIG. 10, time-dependent variations of the thermal diffusion effect and the luminance in a case where multiple rectangular small regions (small windows) Ws of the display cell 50 are caused to blink with respective colors of red (R), green (G), blue (B), and white (W) are measured.

In particular, from among the small windows Ws disposed in a matrix on the display cell 50, the small windows Ws of the respective colors of R, G, and B located above a dotted line DL are caused to blink with 500 nit in such a manner that ON and OFF are repeated in every three seconds. Further, assuming an instantaneous thrust, the small windows Ws of W and the small windows Ws denoted by “PU” above the dotted line DL are caused to blink with white of doubled luminance (1000 nit) and white of tripled luminance (1500 nit), respectively.

It is to be noted that, from among the small windows Ws disposed in a matrix on the display cell 50, the small windows Ws below the dotted line DL are caused to normally light with 500 nit with the respective colors of R, G, B, and W.

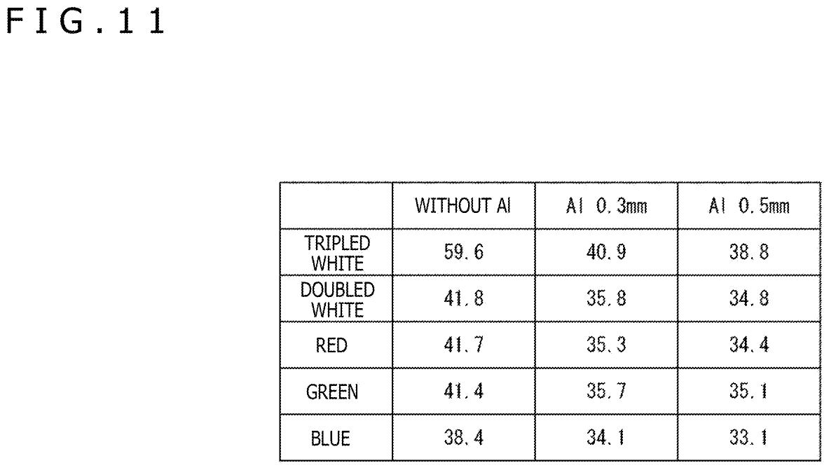

First, a thermal diffusion effect by the heat conduction members 100AL3 and 100AL5 is described with reference to FIG. 11.

FIG. 11 depicts temperatures of the respective small windows Ws on the display cell 50 obtained when the small windows Ws of the respective colors in the region without Al, the region on which the heat conduction member 100AL3 is stuck (Al 0.3 mm), and the region on which the heat conduction member 100AL5 is stuck (Al 0.5 mm) were caused to blink for a fixed period of time.

In the following description, for example, the temperature of the small window Ws of white with tripled luminance is referred to merely as the temperature of tripled white, and the temperature of the small window Ws of red is referred to merely as the temperature of red.

In the region without Al, the temperature of tripled white was 59.6 degrees, the temperature of doubled white was 41.8 degrees, the temperature of red was 41.7 degrees, the temperature of green was 41.4 degrees, and the temperature of blue was 38.4 degrees.

In the region of Al 0.3 mm, the temperature of tripled white was 40.9 degrees, the temperature of doubled white was 35.8 degrees, the temperature of red was 35.3 degrees, the temperature of green was 35.7 degrees, and the temperature of blue was 34.1 degrees.

In the region of Al 0.5 mm, the temperature of tripled white was 38.8 degrees, the temperature of doubled white was 34.8 degrees, the temperature of red was 34.4 degrees, the temperature of green was 35.1 degrees, and the temperature of blue was 33.1 degrees.

From the results depicted in FIG. 11, in the small windows Ws of the respective colors in the region of Al 0.3 mm and the region of Al 0.5 mm, a heat suppression effect of approximately 4 to 7 degrees was found in comparison with the small windows Ws of the respective colors in the region without Al. Especially the tripled white for which a strong instantaneous thrust was assumed exhibited a heat suppression effect of around 20 degrees.

That is, it was confirmed that, in regard to blinking for which an instantaneous thrust was assumed, the thermal diffusion effect by the heat conduction members 100AL3 and 100AL5 was high.

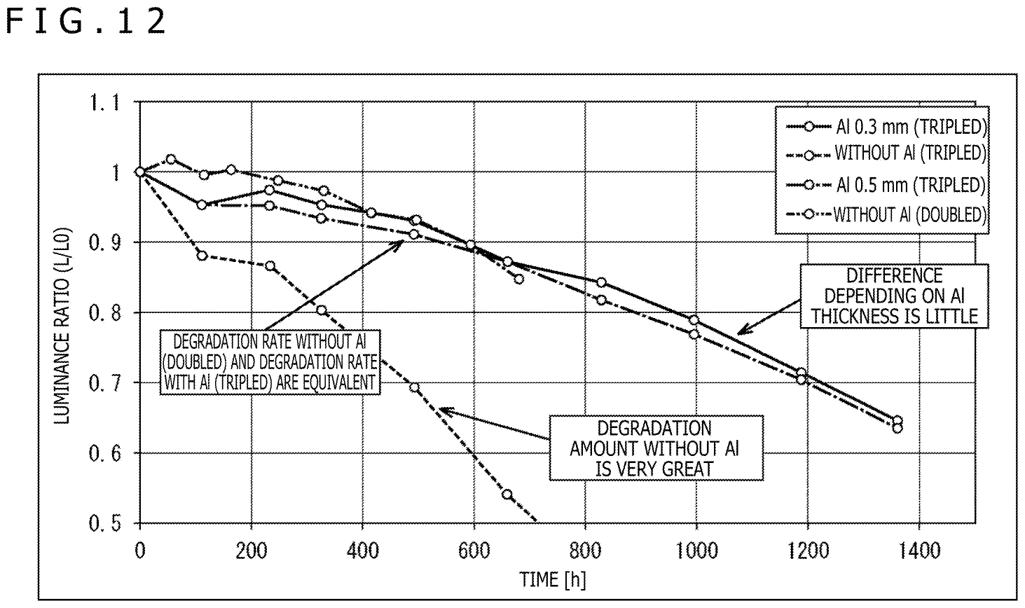

Now, an element degradation suppression effect by the heat conduction members 100AL3 and 100AL5 is described with reference to FIG. 12.

FIG. 12 depicts a graph of luminance ratios with respect to lapse of time, in regard to the small windows Ws of tripled white in the region without Al, the region of Al 0.3 mm, and the region of Al 0.5 mm as well as the small window Ws of doubled white in the region without Al on the display cell 50.

The luminance ratio represents a ratio of luminance L after lapse of predetermined time to luminance L0 at elapsed time 0 [h]. That is, it is indicated that, as the luminance ratio decreases as time elapses, degradation of elements proceeds.

As indicated by a broken line in FIG. 12, it was confirmed that, in regard to the tripled white for which a strong instantaneous thrust was assumed, the degradation amount of the elements was very great and the progress of the degradation was fast in the region without Al.

Further, as indicated by a solid line and an alternate long and short dash line in FIG. 12, it was confirmed that, in regard to the tripled white for which a strong instantaneous thrust was assumed, in the region of Al 0.3 mm and the region of Al 0.5 mm, degrees of the progress of degradation of the elements were substantially the same and there was little difference depending on the thickness of Al.

It is to be noted that also it can be confirmed that the degradation rates of the elements of the tripled white in the regions with Al (region of Al 0.3 mm and region of Al 0.5 mm) and the degradation rate of the elements of the doubled white in the region without Al, which is indicated by an alternate long and two short dashes line in FIG. 12, are equivalent to each other.

From the foregoing, it was confirmed that the element degradation suppression effects equivalent to each other are obtained by the heat conduction members 100AL3 and 100AL5. Especially, in a case where the Al thin plate of 0.3 mm thick and the Al thin plate of 0.5 mm thick are compared with each other, from points of view of cost and weight, it is preferable to adopt 0.3 mm as the thickness of the heat conduction member 100 including Al. In addition, in the case of further increasing luminance at an instantaneous thrust, it is necessary to make the thickness of the heat conduction member 100 including Al greater than 0.3 mm. It is to be noted that it is not preferable to make the thickness of the heat conduction member 100 including Al smaller than 0.3 mm, for example, equal to 0.15 mm, because the thermal diffusion effect is impaired.

### 5. Evaluation of Sound Influence

The technology according to the present disclosure can be applied also to a configuration in which an OLED cell is vibrated by an actuator. Therefore, the applicant also performed evaluation of a sound influence of a heat conduction member 100 on the display cell 50.

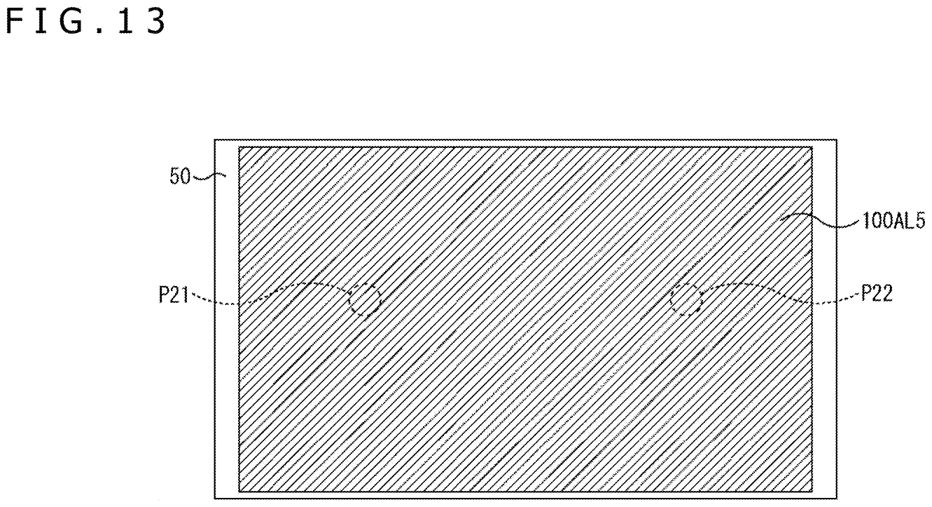

FIG. 13 is a view illustrating a method for evaluating the sound influence of the heat conduction member 100 on the display cell 50.

FIG. 13 depicts a configuration of the rear face side of the display cell 50. A heat conduction member 100AL5 of t0.5 including Al is stuck on substantially the entire rear face of the display cell 50, for example, by a double-sided adhesive tape of 0.05 mm thick. It is to be noted that, in FIG. 13, positions P21 and P22 in the heat conduction member 100AL5 at which the vibration generators 21 and 22 are disposed on the display cell 50 are indicated by broken lines.

In such a state, the influence of the heat conduction member 100AL5 on sound to be outputted when the display cell 50 is vibrated by the vibration generators 21 and 22 is evaluated.

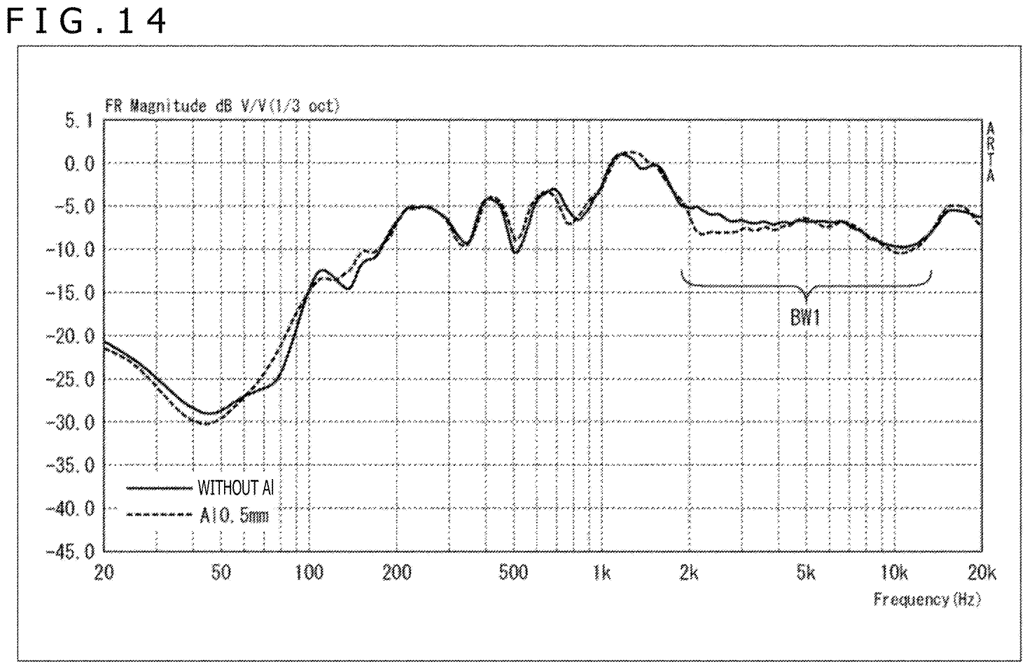

FIG. 14 indicates a result of evaluation of the sound influence of the heat conduction member 100AL5.

FIG. 14 depicts a frequency-sound pressure characteristic of the display cell 50 in a case (without Al) where the heat conduction member 100AL5 is not stuck on the rear face of the display cell 50 and a frequency-sound pressure characteristic of the display cell 50 in a case (Al 0.5 mm) where the heat conduction member 100AL5 is stuck on the rear face of the display cell 50. In FIG. 14, the axis of abscissa indicates the frequency, and the axis of ordinate indicates the sound pressure.

The characteristic of the display cell 50 without Al indicated by a solid line in FIG. 14 and the characteristic of the display cell 50 with Al 0.5 mm indicated by a broken line are substantially equivalent to each other within a range from 20 Hz to 2 kHz. However, in a frequency band BW1 higher than 2 kHz, attenuation of the characteristic of Al 0.5 mm can be seen in comparison with the characteristic without Al.

That is, in the case where the heat conduction member 100AL5 was stuck on the rear face of the display cell 50, it was confirmed that the sound pressure decreases in a high frequency band. It is speculated that this sound pressure decrease in the high frequency band arises from the thickness of the heat conduction member 100AL5. Accordingly, it is considered that, by adopting an Al thin plate of 0.3 mm thick as the heat conduction member 100 in place of the Al thin plate of 0.5 mm thick, the sound pressure decrease in the high frequency band can be suppressed, and the characteristic in this case can be made closer to the characteristic without Al. In other words, by adopting an Al thin plate of 0.3 mm thick as the heat conduction member, a good balance can be established between the output of the actuator and vibration of the OLED cell, and both the thermal diffusion performance and the maintenance of the sound pressure can be achieved. In addition, in a case where the output of the actuator can be increased in response to a sound pressure decrease, it is also possible to adopt an Al thin plate thicker than the Al thin plate of 0.3 mm thick as the heat conduction member.

The embodiment of the technology according to the present disclosure is not restricted to the embodiment described above, and various alterations can be made without departing from the subject matter of the technology according to the present disclosure.

Further, the advantageous effects described in the present specification are exemplary to the last and are not restrictive, and other advantageous effects may be provided.

Moreover, the technology according to the present disclosure can adopt the following configurations:

(1)

A display device including:
a plate-shaped display cell that displays an image; and
a thin plate-shaped heat conduction member stuck on a rear face side of the display cell, in which
the heat conduction member is formed with a thickness of approximately 0.3 to 1.0 mm.
   (2)

The display device according to (1) above, in which
the heat conduction member is formed with a thickness of approximately 0.3 to 0.5 mm.
   (3)

The display device according to (1) or (2) above, in which
the heat conduction member includes aluminum.
   (4)

The display device according to (1) or (2) above, in which
the heat conduction member includes graphite.
   (5)

The display device according to any one of (1) through (4) above, in which
the heat conduction member has a thickness of 0.3 mm.
   (6)

The display device according to any one of (1) through (5) above, in which
the display cell includes an OLED (Organic Light Emitting Diode) cell.
   (7)

The display device according to any one of (1) through (6) above, further including:
multiple vibration generators that are disposed on the rear face side of the display cell and vibrate the display cell.
   (8)

The display device according to (7) above, in which the vibration generators are disposed avoiding a location at which vibration is most likely to occur and another location at which vibration is least likely to occur over overall audio frequencies when the display cell is vibrated by the vibration generators.

### REFERENCE SIGNS LIST

1: Display device
10: Panel unit
19: Back chassis
20: Vibration generation unit
21, 22: Vibration generator
30: Signal processing unit
50: Display cell
60: Back cover
61: Inner plate
70: Fixation member
100: Heat conduction member

1. A display device comprising:
a plate-shaped display cell that displays an image; and
a thin plate-shaped heat conduction member stuck on a rear face side of the display cell, wherein
the heat conduction member is formed with a thickness of approximately 0.3 to 1.0 mm.

2. The display device according to claim 1, wherein
the heat conduction member is formed with a thickness of approximately 0.3 to 0.5 mm.

3. The display device according to claim 1, wherein
the heat conduction member includes aluminum.

4. The display device according to claim 1, wherein
the heat conduction member includes graphite.

5. The display device according to claim 1, wherein
the heat conduction member has a thickness of 0.3 mm.

6. The display device according to claim 1, wherein
the display cell includes an OLED (Organic Light Emitting Diode) cell.

7. The display device according to claim 1, further comprising:
multiple vibration generators that are disposed on the rear face side of the display cell and vibrate the display cell.

8. The display device according to claim 7, wherein
the vibration generators are disposed avoiding a location at which vibration is most likely to occur and another location at which vibration is least likely to occur over overall audio frequencies when the display cell is vibrated by the vibration generators.
